(19) United States
(12) Patent Application Publication
(10) Pub. No.: US 2012/0126378 A1
(43) Pub. Date: May 24, 2012

(54) SEMICONDUCTOR DEVICE PACKAGE WITH ELECTROMAGNETIC SHIELDING

(75) Inventors: Romarico S. San Antonio, San Miguel (PH); Michael H. McKerreghan, Farmers Branch, TX (US); Anang Subagio, Batam Island (ID); Allan C. Toriaga, Asingan (PH)

(73) Assignee: Unisem (Mauritius ) Holdings Limited, Port Louis (MU)

(21) Appl. No.: 12/953,578

(22) Filed: Nov. 24, 2010

(51) Int. Cl. H01L 23/495; H01L 21/60

(52) U.S. Cl. 257/659; 438/123; 257/666; 257/E23.031; 257/E21.51

(57) ABSTRACT

A package for a semiconductor device includes shielding from RF interference. The package has a lead frame with a lead and a connecting bar. The lead has an inner end for connecting to the device and an outer end having an exposed surface at the package side face. The connecting bar also has an end with an exposed surface at the package side face. A molding compound overlying the leadframe forms a portion of the side face. Electrically conductive shielding forms a top surface of the package, and extends downward therefrom to form an upper portion of the package side face. The exposed surface at the connecting bar end has an upper edge higher than the upper edge of the exposed surface of lead end. Accordingly, the shielding makes electrical contact with the connecting bar adjacent to its exposed surface, while being electrically isolated from the lead.

### FIELD OF THE DISCLOSURE

This disclosure relates to packages for semiconductor devices. More particularly, the disclosure relates to quad flat no-lead (QFN) semiconductor device packages shielded against electromagnetic interference (EMI).

### BACKGROUND OF THE DISCLOSURE

In lead frame based semiconductor device packages, electrical signals are transmitted via an electrically conductive lead frame between at least one semiconductor device and external circuitry, such as a printed circuit board. The lead frame includes a number of leads, each having an inner lead end and an opposing outer lead end. The inner lead end is electrically connected to input/output pads on the device, and the outer lead end provides a terminal outside of the package body. Where the outer lead end terminates at the face of the package body, the package is known as a “no-lead” package. Examples of well-known no-lead packages include quad flat no-lead (QFN) packages, which have four sets of leads disposed around the perimeter of the bottom of a square package body. A QFN package, with a method of manufacturing the package, is disclosed in commonly owned U.S. Pat. No. 7,563,648, filed on Aug. 11, 2004 and incorporated by reference in its entirety herein.

In a no-lead package, the semiconductor device is typically connected to the inner lead ends using wire bonding, tape automated bonding (TAB), or flip-chip methods. In wirebonding or TAB methods, the inner lead ends terminate a distance from the device and are electrically interconnected to input/output (I/O) pads on the top of the device by small diameter wires or conductive tape. The device may be supported by a support pad, which is surrounded by the leads. In the flip-chip method, the inner lead ends of the lead-frame extend beneath the device, and the device is flipped such that the I/O pads on the device contact the inner lead ends through a direct electrical connection (e.g., a solder connection).

In modern packaging techniques, a matrix of interconnected lead frames is used to allow a number of packages to be manufactured at the same time. Such techniques generally include securing a device to a central support pad of each lead frame in the matrix using solder, epoxy, double-sided adhesive tape, or the like. The leads for each lead frame are then wirebonded to I/O pads on the device. After wirebonding, the device, bond wires, and at least a portion of the leads are encapsulated in plastic using, for example, a transfer or injection molding process. The packages are then singulated by sawing or punching, leaving portions of the leads of each package exposed for electrical connection to an external circuit.

A typical singulated QFN package, where the device is connected using wirebonding techniques, is shown in cross-section view in FIG. 1A. Device 1 is secured to support pad 3 by adhesive layer 2, wires 4 connect I/O pads on the upper surface of the device to leads 14. The device, wirebond connections, and leads are covered by molding compound 5 (e.g. a polymer resin). Package 11 is then separated from adjacent packages by sawing with a blade, water jet, or the like; the sawing operation leaves a package face with a portion of lead 14 exposed.

In another QFN package arrangement, shown in FIG. 1B, package 12 has features similar to package 11 except that the leads 15 are etched to remove approximately half their thickness prior to sawing. The leads 15 are thus referred to as “half-etched” leads, while leads 14 are “full” leads. Molding compound 5 covers the leads so that, after singulation, package 12 has a corner 17 of molding compound rather than conductive material.

A QFN package with full leads and singulated by a punching process is shown in FIG. 1C. In package 13, the molding compound has a sloped side 18 and leads 16 have a portion of their upper surface exposed.

In packages 11-13, semiconductor device 1 is encased in the molding compound 5 (for example, a block of polymer resin), which provides environmental protection for the device. However, such a device is still susceptible to electromagnetic interference (EMI), particularly radio-frequency (RF) interference which degrades the performance of the device. Accordingly, it is desirable to provide a semiconductor device package with EMI shielding as well as environmental shielding.

In the QFN packages described above, providing RF shielding presents a challenge which may be understood with reference to FIG. 2. FIG. 2 shows in top planar view four packages with adjacent corners prior to singulation. Each package has a device support pad 21 and leads 22 (only four leads opposite each pad are shown in FIG. 2). The pads 21 are connected by connecting bars 25; the leads are connected by connecting bars 28. The pads are typically coplanar with the connecting bars as well as coplanar with the neighboring ends of the leads (for example, in package 11 upper surface 8 of pad 3 is coplanar with upper surface 9 of lead 14). An effective RF shield should make electrical contact with the pads, but not with the coplanar leads. After singulation (cutting along boundary lines 26 and thereby removing connecting bars 28), each package will have faces with the leads 22 and connecting bars 25 exposed at 23 and 27 respectively. It is desirable to provide an RF shield for a package so that the device is shielded both above and below, i.e. covering the top of the molding compound and also connecting to the conductive support pad, while avoiding shorting to the leads.

### SUMMARY OF THE DISCLOSURE

In accordance with an aspect of the disclosure, there is provided a package for a semiconductor device with shielding from RF interference. The package includes a lead frame having a lead and a connecting bar. The lead has an inner end for connecting to the device and an outer end extending to a side face of the package with an exposed surface. The connecting bar has an end extending to the side face of the package, also with an exposed surface. A molding compound overlies the leadframe and forms a portion of the side face of the package. Electrically conductive shielding overlies the molding compound above the leadframe to form a top surface of the package, and extends downward therefrom to form an upper portion of the side face of the package. The exposed surface at the end of the connecting bar has an upper edge displaced vertically with respect to the upper edge of the exposed surface of the end of the lead. Accordingly, the shielding makes electrical contact with the connecting bar adjacent to its exposed surface, while being electrically isolated from the lead.

In accordance with another aspect of the disclosure, a method for manufacturing a package for a semiconductor device includes the following steps: A leadframe is provided which includes a lead and a connecting bar, where the lead and the connecting bar each have a top surface and a bottom surface. Recesses are formed in the lead and the connecting bar at their respective outer ends (adjacent to a boundary of the leadframe); the recess in the lead is formed with respect to its top surface thereof, and the recess in the connecting bar is formed with respect to its bottom surface. A molding compound is applied to cover the leadframe. A cutting process is then performed to make a cut extending vertically partially through the molding compound at the boundary of the leadframe and aligned with the first and second recesses, thereby exposing a portion of the connecting bar. A layer of electrically conductive shielding material is formed, overlying the molding compound and on the sides and the bottom of the cut, so that the shielding material is in electrical contact with the exposed portion of the connecting bar. A singulation process is then performed at the boundary of the leadframe and aligned with the cut, thereby forming a package side face. The package side face thus includes shielding material disposed on an upper portion thereof, an exposed portion of the molding compound, an exposed surface at the outer end of the lead, and an exposed surface at the end of the connecting bar.

In the above-described method, the molding compound may be applied using a block molding process. According to still another aspect of the disclosure, the molding compound is applied using a pocket molding process, so that a portion of the leadframe adjacent to the boundary of the leadframe is not covered by the molding compound. The layer of electrically conductive shielding material thus contacts that portion of the leadframe without the need for a cutting process. The subsequent singulation process may be performed by sawing or punching.

Details of various embodiments of the invention are set forth in the accompanying drawings and the description below. Other features, objects and advantages of the invention will be apparent from the description and drawings, and from the claims.

### BRIEF DESCRIPTION OF THE DRAWINGS

FIG. 1A schematically illustrates in cross-section view a QFN package with full leads and singulated by sawing.

FIG. 1B schematically illustrates in cross-section view a QFN package with half-etched leads and singulated by sawing.

FIG. 1C schematically illustrates in cross-section view a QFN package with full leads and singulated by punching.

FIG. 2 schematically illustrates in top planar view four QFN packages with adjacent corners prior to singulation.

FIGS. 3A and 3B illustrate half-etching of leads and connecting bars respectively, in accordance with an embodiment of the disclosure.

FIGS. 4A-4F illustrate formation of shielded and singulated device packages, in accordance with an embodiment of the disclosure.

FIGS. 5A and 5B are detail views of the partial saw cuts of FIG. 4D at the leads and connecting bars respectively.

FIGS. 5C and 5D are detail views of deeper partial saw cuts than in FIGS. 5A and 5B at the leads and connecting bars respectively.

FIGS. 6A and 6B are detail views of the leads and connecting bars of FIGS. 5A and 5B respectively, with the narrow saw cuts of FIG. 4F.

FIGS. 6C and 6D are detail views of the leads and connecting bars of FIGS. 5C and 5D respectively, with the narrow saw cuts of FIG. 4F.

FIG. 7 is a top perspective view of a lead frame of a semiconductor device package according to an embodiment of the disclosure.

FIG. 8 is a detail view of a corner of the lead frame of FIG. 7.

FIG. 9 is a detail view showing a corner of a package having electromagnetic shielding, according to an embodiment of the disclosure.

FIGS. 10A and 10B illustrate formation of shielded device packages where the packages are formed using a block molding process, in accordance with an embodiment of the disclosure.

FIGS. 11A and 11B illustrate formation of shielded device packages where the packages are formed using a pocket molding process, in accordance with another embodiment of the disclosure.

FIG. 12 illustrates formation of shielded device packages where the packages are formed using a pocket molding process, in accordance with still another embodiment of the disclosure.

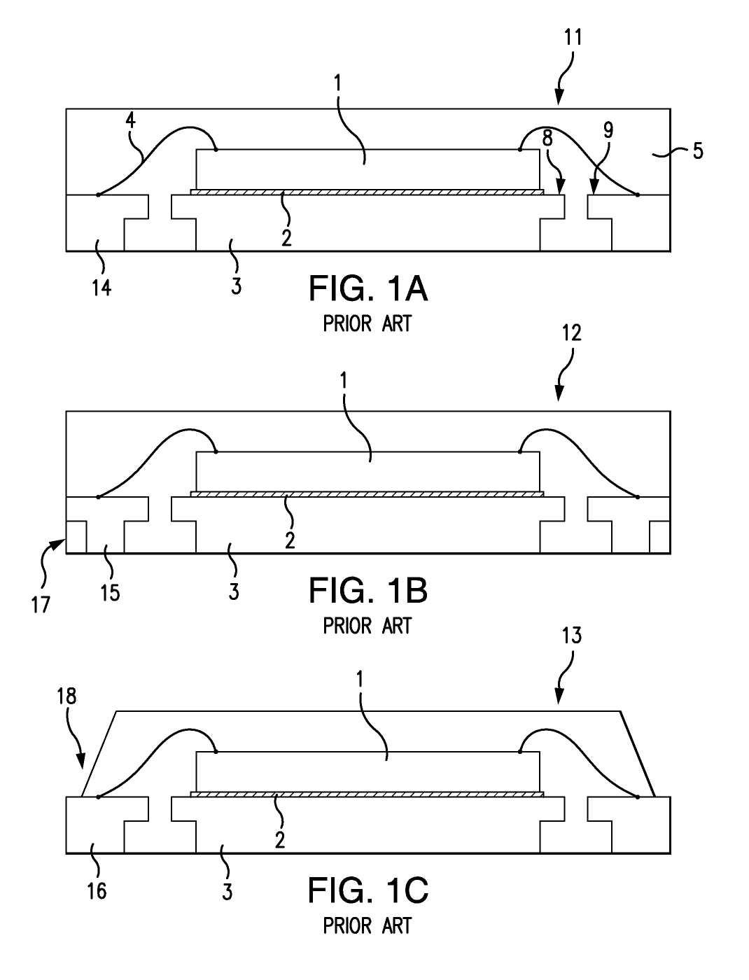

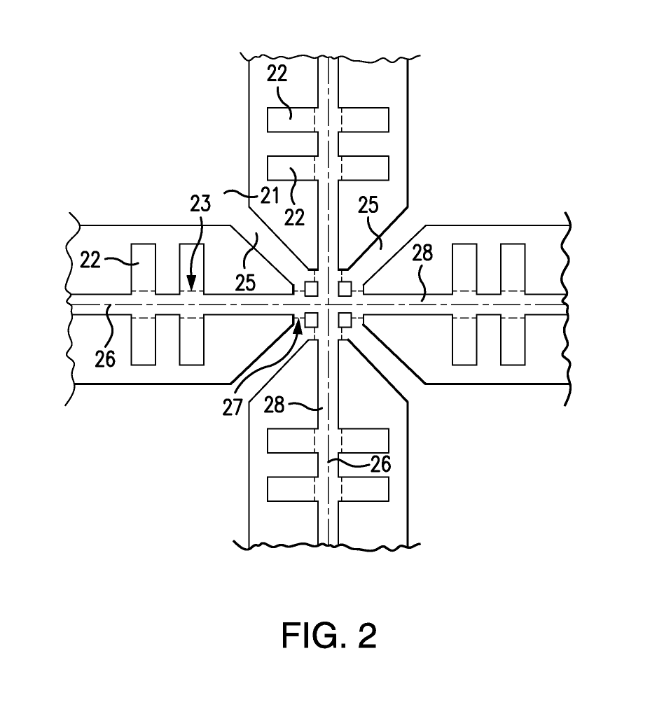

### DETAILED DESCRIPTION

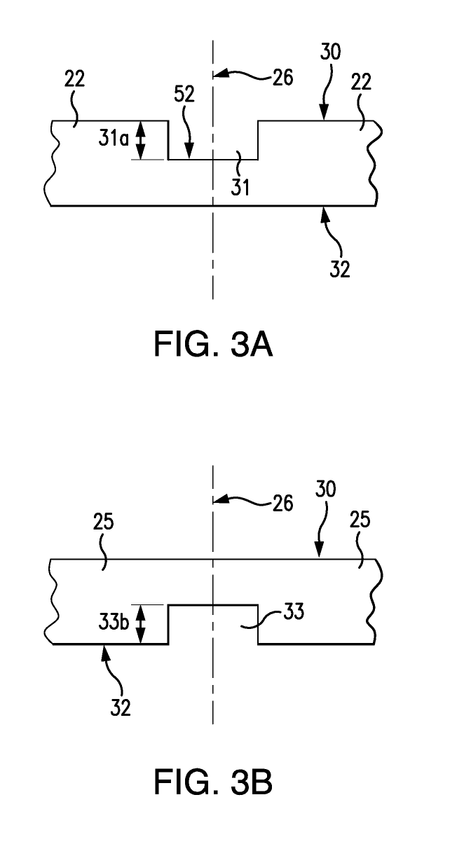

In accordance with an embodiment of the disclosure, a QFN package is formed having both half-etched leads and half-etched connecting bars. FIG. 3A shows leads 22 of adjacent leadframes; these leads are to be separated along boundary 26 in the singulation process. The leads are etched from top surface 30 so that a recess 31 is formed therein, with boundary 26 approximately at the centerline thereof. Recess 31 has a depth 31a which is approximately half the thickness of the leads 22; surface 52 forms the bottom of recess 31.

As shown in FIG. 3B, connecting bars 25 are etched from bottom surface 32, so that a recess 33 is formed therein, with boundary 26 approximately at the centerline thereof. Recess 33 has a depth 33b which is approximately half the thickness of the connecting bars 25. In the embodiment shown in FIG. 3B, recess 33 is only slightly wider than the singulation path. In other embodiments, recess 33 may extend laterally towards the die pad so that all or substantially all of connecting bar 25 is half-etched.

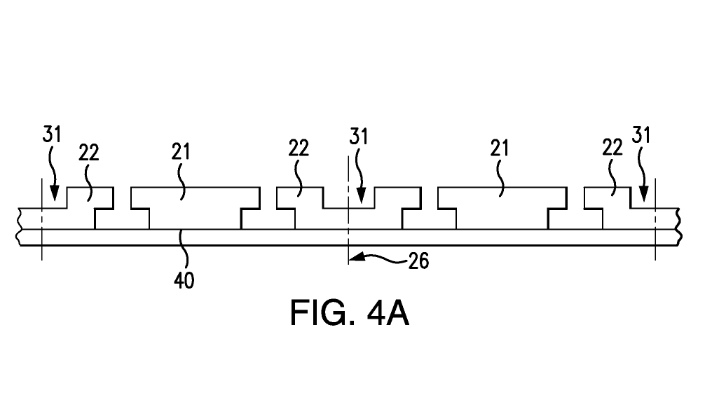

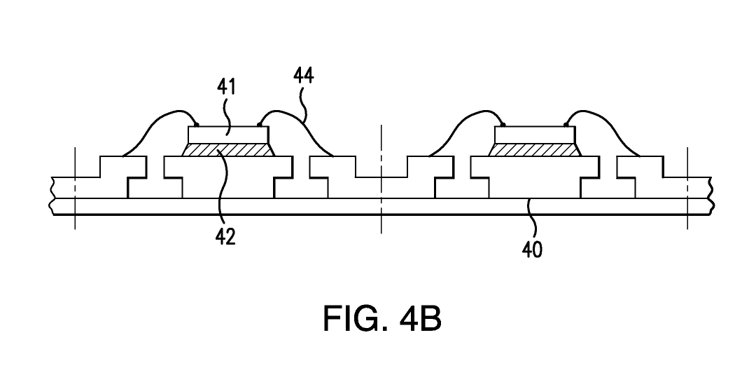

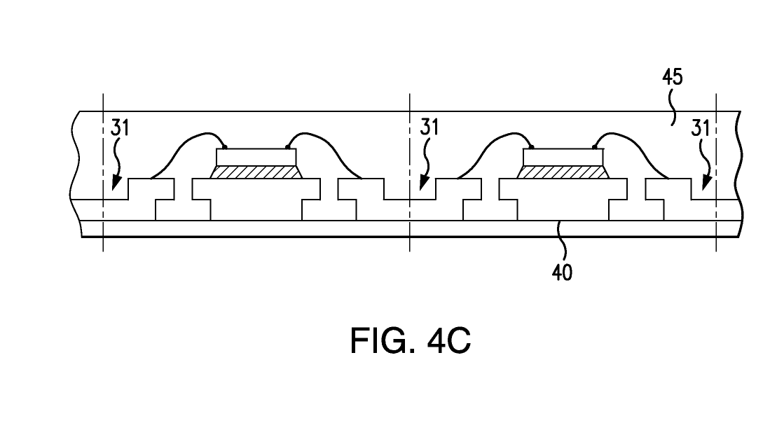

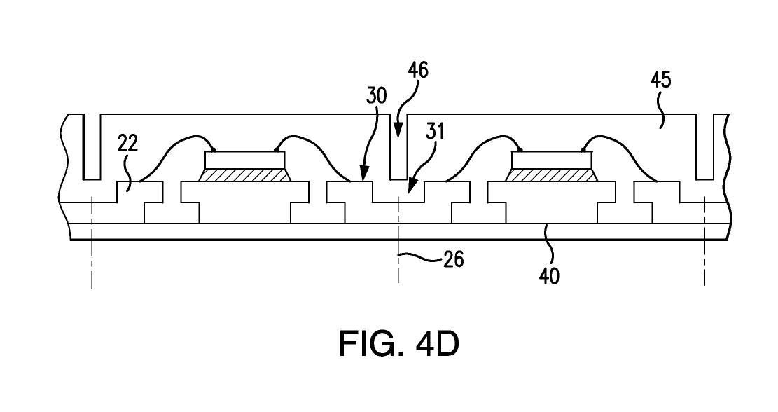

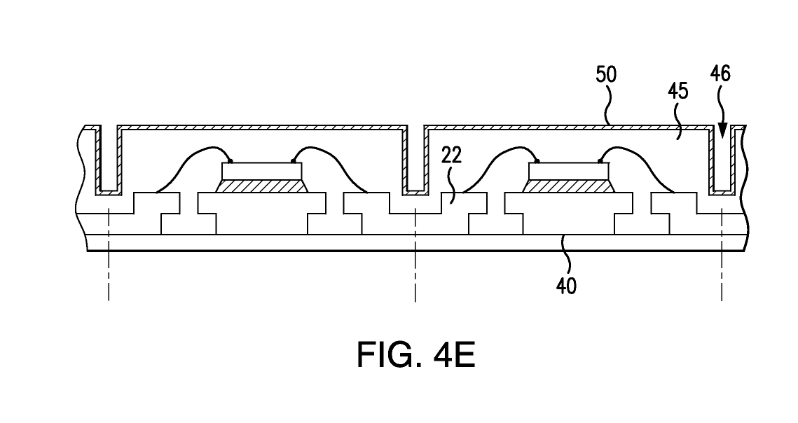

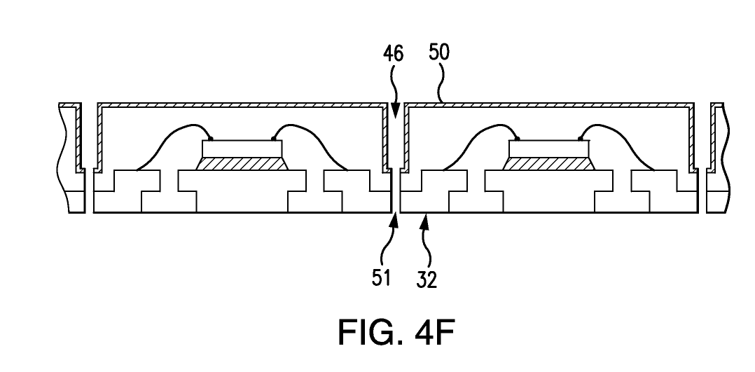

A cross-section view of the leadframes after the half-etching process is given in FIG. 4A. In each of the adjacent leadframes (that is, prior to singulation), each lead 22 has an inner end closest to the pad 21 and an outer end that extends to boundary 26. After recesses 31 and 33 are formed in the respective half-etching processes, the substantially coplanar bottom surfaces of the device support pad 21, the leads 22 and the connecting bars 25 are adhered to a surface 40. In the embodiment shown, the surface 40 is formed on an adhesive tape. Devices 41 are then attached to the support pads using adhesive material 42, and connected to the leads by wires 44, as shown in FIG. 4B. The devices are encapsulated by molding compound 45, as shown in FIG. 4C. Furthermore, molding compound 45 covers the exposed surfaces of the leadframe and fills recesses in the leadframe at both the top and bottom surfaces thereof, including recesses 31 and 33.

A partial singulation process is then performed, as shown in FIG. 4D; saw cuts 46 are made along boundary lines 26. The depth of the saw cut is such that the bottom of the cut is even with, or slightly below, the plane of the top surface 30 of the leads 22.

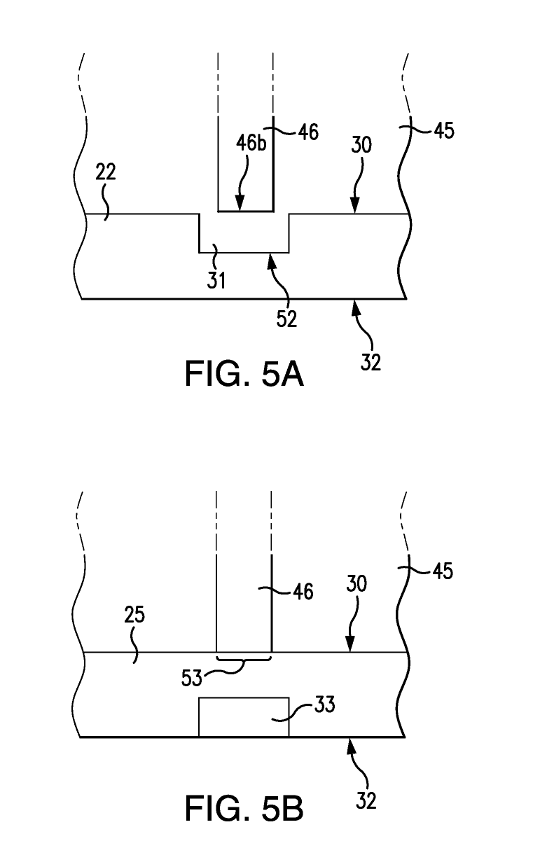

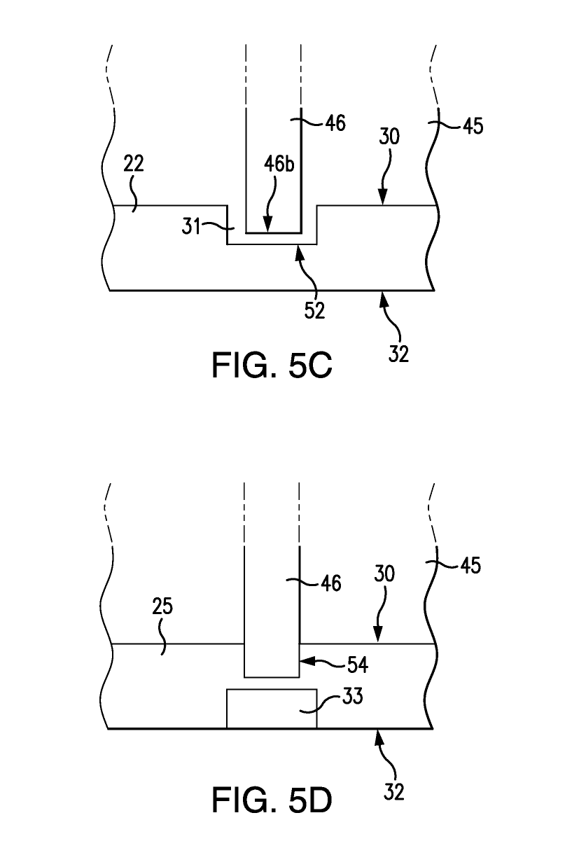

FIGS. 5A and 5B are detail views showing the result of the partial cutting process with respect to the leads and connecting bars. As shown in FIG. 5A, the bottom 46b of saw cut 46 is approximately coplanar with the top surface 30 of leads 22. However, the lead is not exposed, because the saw cut is aligned with recess 31; accordingly, the bottom of the cut 46b does not extend to the metal surface 52 at the bottom of recess 31. The width of the saw blade is chosen to be substantially narrower than recess 31, so that minor misalignment of the saw will not result in the lead being exposed. In contrast, as shown in FIG. 5B, saw cut 46 extends down at least to the plane of the top surface of connecting bars 25, so that a portion 53 of the connecting bar surface is exposed.

FIGS. 5C and 5D illustrate the process window available with respect to the depth of saw cut 46. In FIG. 5C, the saw cut is deeper than in FIG. 5A, but the surface of the lead is not exposed as long as the bottom of the saw cut remains above recessed surface 52. Accordingly, the process window for the depth of saw cut 46 is related to the depth 31a of recess 31. Similarly, in FIG. 5D the saw cut is deeper than in FIG. 5B, so that saw cut 46 extends further into connecting bars 25, exposing a vertical surface 54 in addition to surface portion 53.

In an embodiment, the thickness of the leadframe (that is, the distances between surfaces 30 and 32) is 8 mils (0.008 inches or 0.02 mm), and the depths 31a and 33b of recesses 31 and 33 are typically 50% to about 65% of the thickness of the leadframe, or 4 mils (0.004 inches or 0.10 mm) to about 5.2 mils (0.0052 inches or 0.13 mm). Accordingly, saw cut 46 in FIG. 5D may extend about 0.05 mm (50 μm) past surface 30 to ensure that surface portion 53 is exposed while avoiding exposing surface 52.

A conductive material 50 for RF shielding is deposited on the top surface of molding compound 45 and on the side and bottom surfaces of saw cut 46, as shown in FIG. 4E. The shielding material may be applied by a variety of processes, e.g. spraying, dipping, immersion, electroplating, etc. As shown in FIG. 4E, the shielding material 50 does not make contact with the leads 22. However, since the saw cut 46 exposes a portion 53 of the connecting bar surface, the shielding material contacts the connecting bars 25.

In this embodiment, the protective adhesive tape on the bottom surface is removed after material 50 is deposited. Alternatively, if the RF shielding material is the same as the finish material of the lead frame (e.g. Sn), the shielding may be deposited after the tape is removed. Electroless or electrolytic plating of the shielding material may also be performed after the tape is removed.

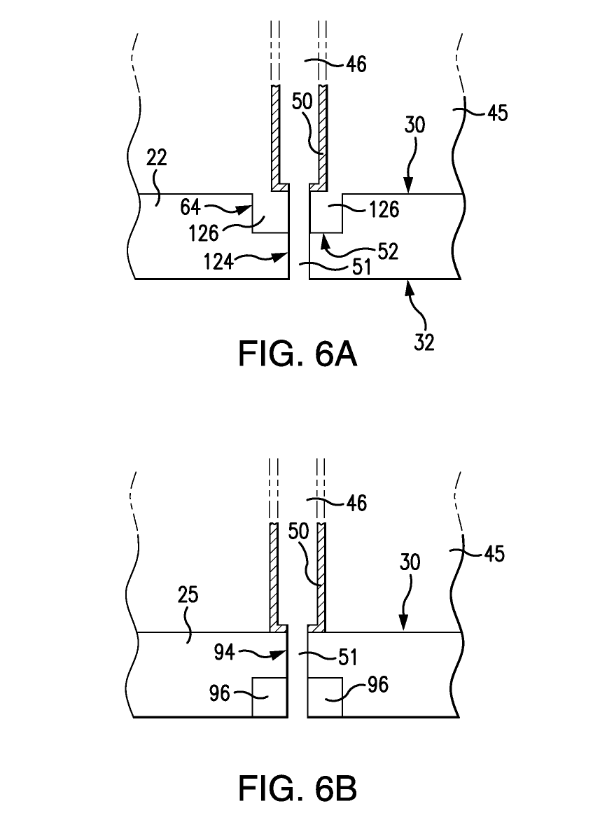

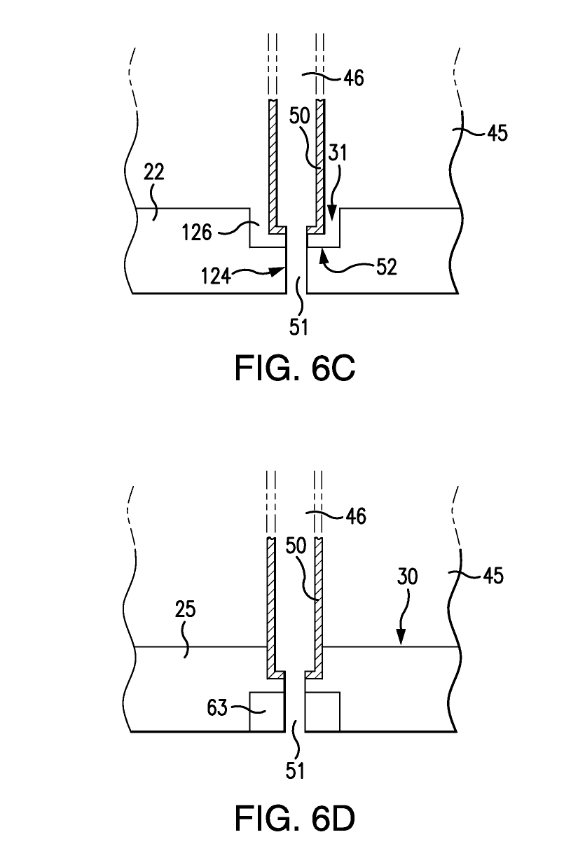

Final singulation is performed by a second saw cutting process making saw cuts 51, as shown in FIG. 4F. In this embodiment, a narrower saw blade is used than for the first saw cut. FIGS. 6A and 6B are detail views showing the result of the second saw cut at the leads and connecting bars, respectively. In both FIGS. 6A and 6B, the shielding material 50 is disposed on side faces of the respective singulated packages, and extends downward to the plane of the top surface 30 of the leadframe. Owing to the half-etch processes described above, the shielding material 50 does not contact the leads 22, but does contact the connecting bars 25. As shown in FIG. 6A, saw cut 51 exposes an area 124 at the end of lead 22 and adjacent to the bottom surface 32 of the leadframe. Saw cut 51 divides recess 31 (filled with molding compound 45) into two segments 126, each adjacent to top surface 30. The side wall 64 of recess segment 126 is not exposed and is separated from shielding material 50 by molding compound 45. As shown in FIG. 6B, saw cut 51 exposes an area 94 at the end of connecting bar 25 and adjacent to the top surface 30 of the leadframe. Shielding material 50 extends down to, and is contiguous with, exposed area 94. Saw cut 51 divides recess 33 (filled with molding compound 45) of connecting bar 25 into two segments 96, each extending laterally from the corner formed by saw cut 51 and bottom surface 32. As noted above with reference to FIG. 3B, recess 33 may extend laterally towards the die pad so that all or substantially all of connecting bar 25 is half-etched. Accordingly, in each singulated package, recess 96 may extend along the entire length of connecting bar 25.

The upper edge of exposed area 124 is defined by the intersection of area 124 with surface 52; the upper edge of exposed area 94 is defined by the intersection of area 94 with surface 30. Surface 30 is higher than surface 52, as a result of the formation of recess 31. The vertical displacement of the respective upper edges of areas 94 and 124 on the package side face is thus determined by the depth 31a of recess 31.

In the case where the first saw cut extends below the plane of the top surface 30 of the leadframe (FIGS. 5C and 5D), the result of the second saw cut is as shown in FIGS. 6C and 6D respectively. In FIG. 6C, the shielding material 50 extends further toward the end of the lead 22 than in FIG. 6A, but still does not make contact with the lead. In FIG. 6D, the shielding material 50 overlies an exposed end of connecting bar 25, and accordingly makes electrical contact with the connecting bar as in FIG. 6B.

The second saw cut process has a wide process window with regard to the depth of the cut 51. Saw cut 51, extending from surface 32, need only break through the shielding material at the bottom of saw cut 46; the depth of saw cut 51 thus does not depend on the depth of cut 46. The width of the second saw blade is chosen so that the second saw cut breaks through the bottom of saw cut 46 even if there is minor misalignment of the first and second saw blades, and so that the second saw blade does not damage shielding material 50 on the side walls of saw cut 46. The difference in saw blade widths should therefore be at least twice the thickness of the deposited shielding material. The second saw cut process is advantageously performed with the leadframe turned bottom up, so that the second saw cut is made downward from surface 32.

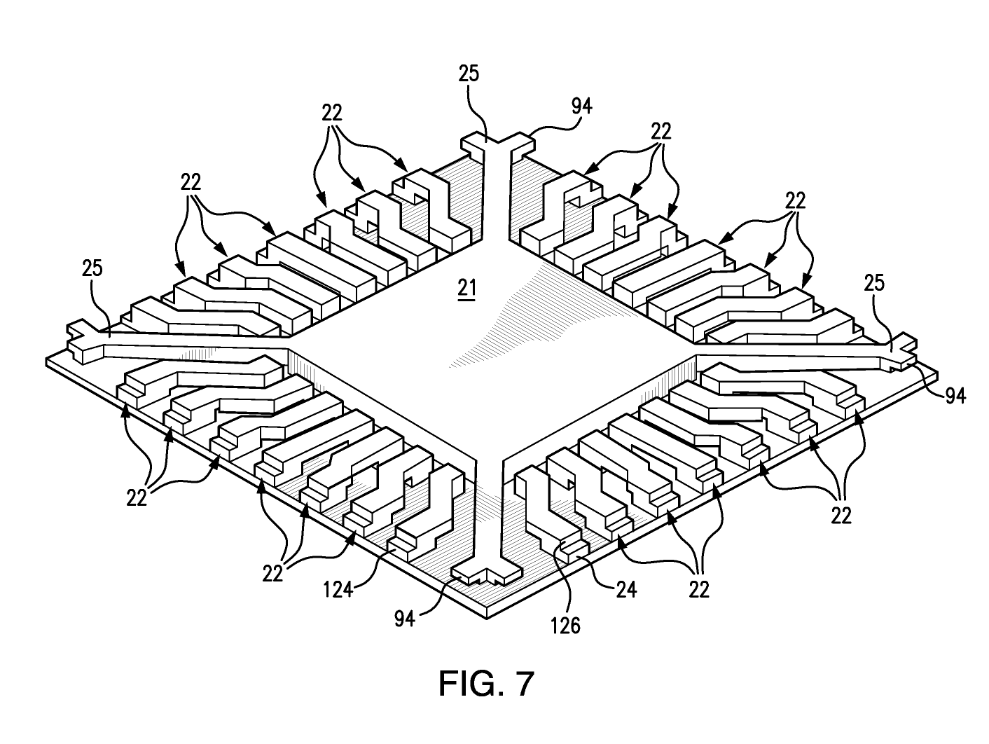

The leadframe of a singulated package according to an embodiment of the disclosure is shown in FIG. 7. (The molding compound and shielding material are omitted for clarity.) The leads 22, with their inner ends opposite device support pad 21, extend to the four sides of the package so that surfaces 124 at their outer ends are exposed at the side faces of the package. The connecting bars 25, integral with device support pad 21, extend diagonally from the pad toward the corners of the package. The connecting bars terminate at surfaces 94 exposed at the side faces of the package.

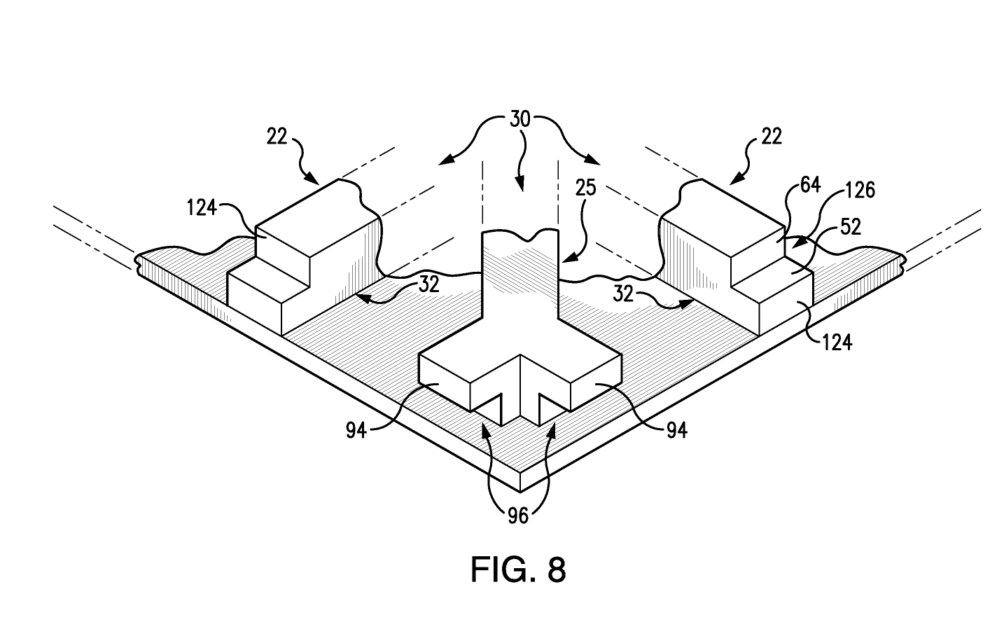

FIG. 8 is a detail view showing one corner of the leadframe of FIG. 7. The leads 22 and connecting bar 25 have coplanar top surfaces 30 and bottom surfaces 32. It is understood that surfaces 30 and 32 extend to the top and bottom surfaces of the die pad respectively. At the package side faces, however, leads 22 have recesses 126, while connecting bar 25 has recesses 96. Exposed surfaces 124 and 94 are thus at different heights with respect to the top and bottom surfaces. As noted above, since surface 30 is higher than surface 52, the top edges of exposed surfaces 124 and 94 have a vertical displacement given by the depth 31a of the recess 31 in the leads. As noted above with reference to FIGS. 3B and 6B, recess 96 may extend from the package face toward the die pad, so that connecting bar 25, while having a top surface 30 coplanar with the leads 22, may have a thickness approximately half that of the leads.

FIG. 9 shows the same leadframe corner with molding compound 45 and shielding material 50 included. Shielding material 50 overlies molding compound 45 and forms the top surface of the package, and extends downward to form the upper portions of the sides of the package. Surfaces 94 are displaced vertically with respect to surfaces 124, which are adjacent to the bottom surface of the leadframe. Shielding material 50 is contiguous with surfaces 94, and is thus electrically connected to connecting bar 25 and device support pad 21, but is isolated from surfaces 124. RF shielding thus is provided above, around and below the device, while the leads of the package have exposed surfaces 124 for electrical connection to an external circuit.

FIG. 9 illustrates the case where the saw cut 46 exposes the top surface of the connecting bar 25, but does not substantially cut into the connecting bar (see FIG. 6B). In that instance, shielding 50 is in contact with the connecting bar but does not substantially overlie the exposed end surface 94. In the case where the saw cut 46 is deeper (see FIG. 6D), the shielding overlies at least a portion of the end of the connecting bar, so that the exposed surface at the end of the connecting bar is reduced in height.

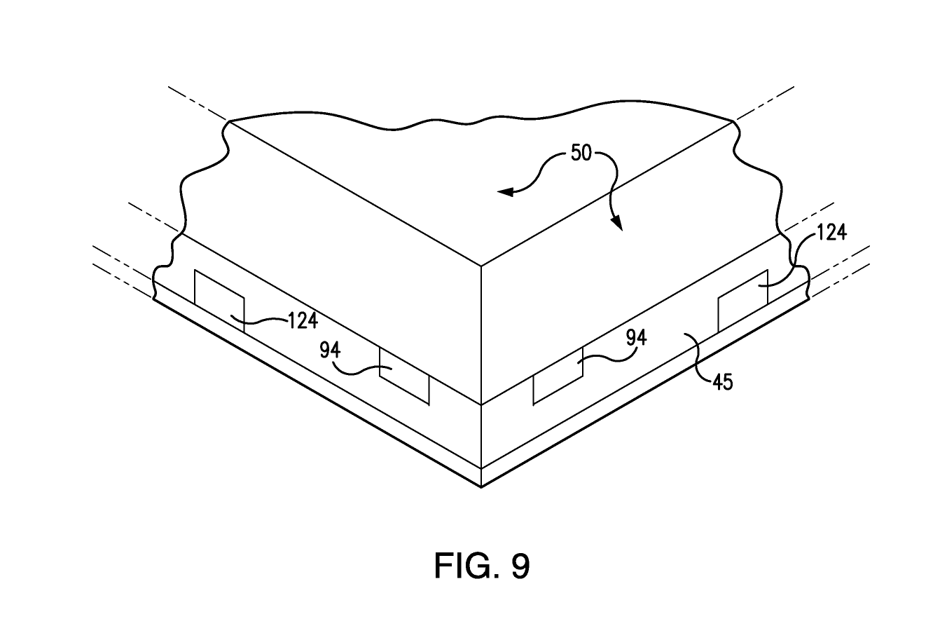

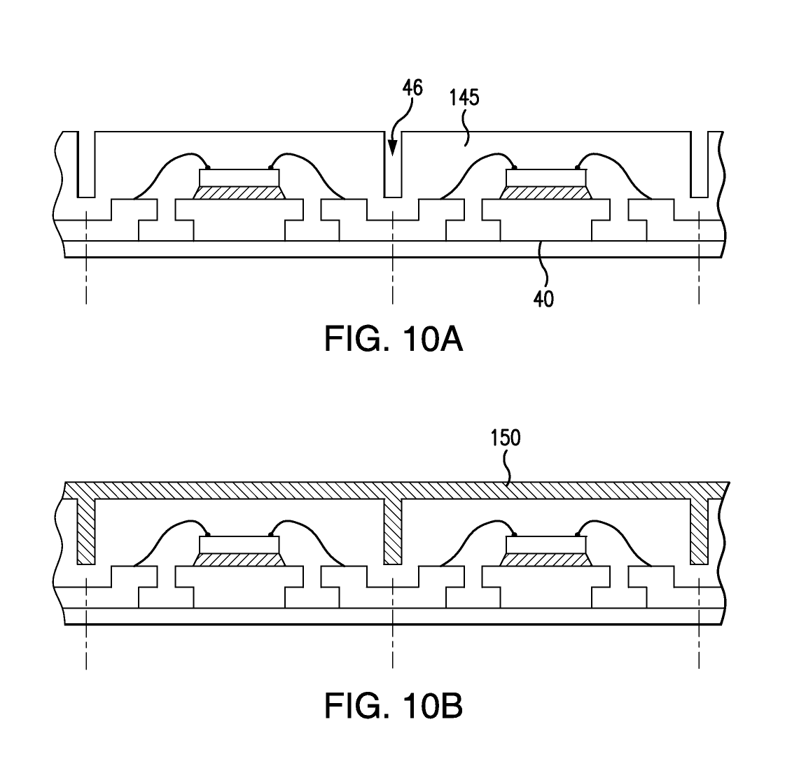

It will be appreciated that the molding compound (e.g. polymer resin) may be applied either by block molding or pocket molding. Furthermore, the shielding material may be applied in a molding process. FIGS. 10A and 10B illustrate formation of a block-molded package with a molded shield, according to an embodiment of the disclosure. In a block molding process, an array of leadframes are covered with molding compound 145, so that the leadframe portions intended for connection to the shield are not exposed. A partial cutting process (FIG. 10A) is therefore needed to expose a portion of each leadframe. Shielding material 150 may then be applied over the molding compound (e.g. by an injection molding process), filling the saw cuts 46, contacting the leadframes, and forming a layer on top of the packages (FIG. 10B). The packages may be singulated using a convenient process (sawing, laser cutting, water ablation, etc.).

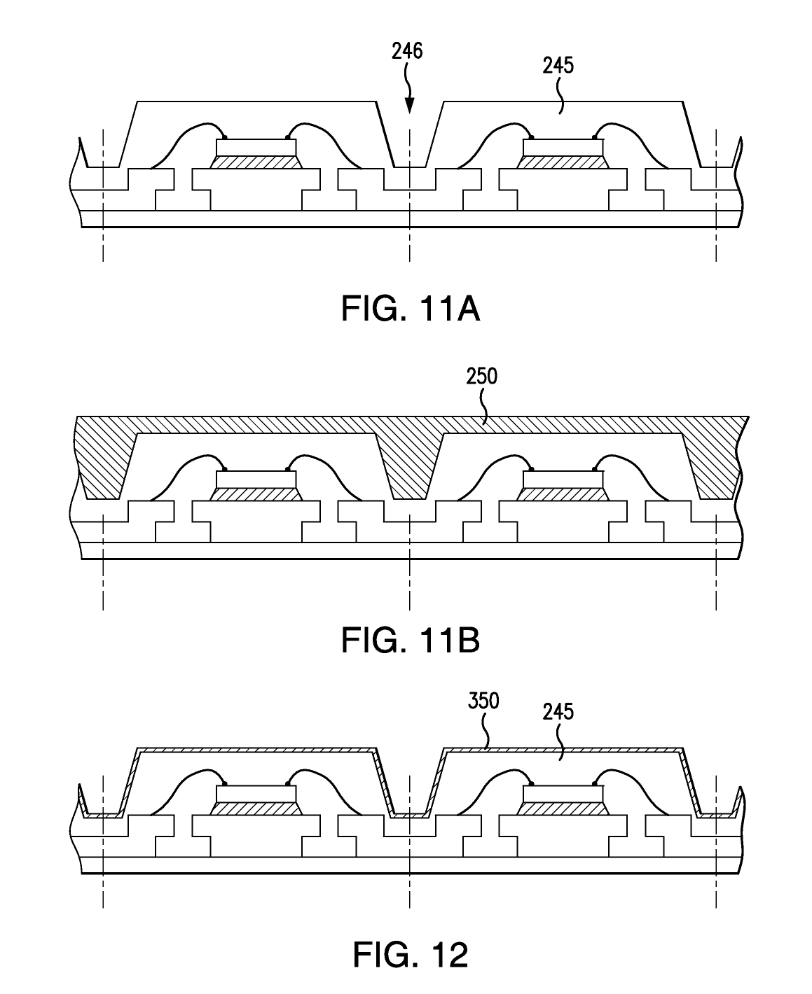

FIGS. 11A and 11B illustrate formation of a pocket-molded package with a molded shield, according to a further embodiment of the disclosure. In FIG. 11A shows an array of leadframes with molding compound 245 applied by pocket molding. The pocket molding process leaves cavities 246 in molding compound 245 along the boundaries between the leadframes (FIG. 11A). Accordingly, the leadframe portions intended for connection to the shield are exposed (in these embodiments, the outer ends of the connecting bars). A partial cutting process is therefore not needed. Shielding material 250 may then be applied over the molding compound (e.g. by an injection molding process), filling the cavities 246, contacting the leadframes, and forming a layer on top of the packages (FIG. 11B). As in the previous embodiment, the packages may be singulated using any of a variety of processes.

In another embodiment, shown in FIG. 12, an array of leadframes is formed with molding compound 245 applied by pocket molding, as in FIG. 11A; a conformal layer of conductive material 350 for RF shielding is then deposited on the top surface of molding compound 245. The shielding material 350 may be applied by spraying or another convenient process (e.g. dipping, immersion, electroplating, etc.). In this embodiment, the packages may be singulated by punching as well as sawing, laser cutting, water ablation, etc.

The packages described above each have a single device attached to the support pad and wired to the leads. In further embodiments of the disclosure, multiple devices may be attached to the pad, either in a single layer or in a stacking arrangement. Passive components may also be included in the package and wired to the devices and/or the leads, before the RF shielding is applied; accordingly, a shielded system-in-package may be provided. In additional embodiments, the device may be attached to the leads in a flip-chip arrangement. To provide more complete shielding for the device, a conductor connected to the shielding but not in contact with the device may be disposed beneath the device (that is, opposite the device and spaced apart from the device).

While the disclosure has been described in terms of specific embodiments, it is evident in view of the foregoing description that numerous alternatives, modifications and variations will be apparent to those skilled in the art. Accordingly, the disclosure is intended to encompass all such alternatives, modifications and variations which fall within the scope and spirit of the disclosure and the following claims.

What is claimed is:

1. A package for a semiconductor device, comprising:
a leadframe including
a lead having an inner end for connecting to the device and an outer end extending to a side face of the package, the outer end of the lead having a first surface exposed at the side face of the package, and
a connecting bar having an end extending to the side face of the package, said end of the connecting bar having a second surface exposed at the side face of the package;
a molding compound overlying the leadframe and forming a portion of the side face of the package; and
electrically conductive shielding overlying the molding compound above the leadframe to form a top surface of the package and extending downward therefrom to form an upper portion of the side face of the package,
wherein the second surface has an upper edge displaced vertically with respect to an upper edge of the first surface, and
the shielding makes electrical contact with the connecting bar adjacent to the second surface while being electrically isolated from the lead.

2. A package according to claim 1, further comprising a support pad for the device connected to the connecting bar and thereby connected to the shielding.

3. A package according to claim 2, further comprising the semiconductor device, the semiconductor device being attached to the support pad and electrically connected to the lead.

4. A package according to claim 1, wherein
the leadframe has a top surface and a bottom surface,
the lead and the connecting bar have top surfaces and bottom surfaces which except at recessed portions are coplanar with the top surface and the bottom surface of the leadframe respectively.

5. A package according to claim 4, wherein the outer end of the lead has a recessed portion with respect to the top surface of the leadframe, so that the first surface is adjacent to the bottom surface of the leadframe while the upper edge of the first surface is below the top surface of the leadframe.

6. A package according to claim 5, wherein said recessed portion has an upper surface below the top surface of the connecting bar.

7. A package according to claim 4, wherein at least an end portion of the connecting bar has a recessed portion with respect to the bottom surface of the leadframe, so that the second surface is adjacent to the top surface of the leadframe while a lower edge of the second surface is above the bottom surface of the leadframe.

8. A package according to claim 1, wherein the shielding overlies a portion of the end of the connecting bar at the side face of the package.

9. A package according to claim 4, wherein
the leadframe has a thickness given by the distance between the top surface and the bottom surface thereof,
the outer end of the lead is recessed with respect to the top surface of the leadframe by approximately half said thickness, and
the end of the connecting bar is recessed with respect to the bottom surface of the leadframe by approximately half said thickness.

10. A package according to claim 1, further comprising the semiconductor device, the semiconductor device being attached to the leads in a flip-chip arrangement.

11. A package according to claim 10, further comprising a conductor connected to the connecting bar and disposed opposite the semiconductor device and spaced apart therefrom.

12. A method for manufacturing a package for a semiconductor device, comprising:
providing a leadframe including a lead and a connecting bar, the leadframe having a top surface and a bottom surface,
forming a first recess in the lead with respect to the top surface at an outer end of the lead adjacent to a boundary of the leadframe;
forming a second recess in the connecting bar with respect to the bottom surface at least at an end of the connecting bar adjacent to the boundary of the leadframe;
applying a molding compound covering the leadframe;
performing a cutting process to form a cut extending vertically partially through the molding compound at the boundary of the leadframe and aligned with the first recess and the second recess, thereby exposing a portion of the connecting bar,
forming a layer of electrically conductive shielding material overlying the molding compound and on the sides and the bottom of the cut, so that the shielding material is in electrical contact with said exposed portion of the connecting bar;
performing a singulation process at the boundary of the leadframe and aligned with the cut, thereby forming a package side face, the package side face including
shielding material disposed on an upper portion thereof,
an exposed portion of the molding compound,
an exposed first surface at the outer end of the lead, and
an exposed second surface at the end of the connecting bar.

13. A method according to claim 12, wherein the leadframe further comprises a device support pad connected to the connecting bar.

14. A method according to claim 13, further comprising providing the semiconductor device, attaching the semiconductor device to the support pad and electrically connecting the semiconductor device to the lead.

15. A method according to claim 12, wherein
top surfaces and bottom surfaces of the lead and the connecting bar are respectively substantially coplanar, so that the lead and the connecting bar each have a substantially equal thickness, and
the first recess and the second recess are each formed with a depth approximately half said thickness.

16. A method according to claim 12, wherein said cutting process is performed using a saw having a first thickness, and said singulation process is an additional cutting process performed using a saw having a second thickness less than the first thickness.

17. A method according to claim 12, wherein said cutting process is performed using a saw, and said singulation process is a punching process.

18. A method according to claim 12, wherein the leadframe is disposed on an adhesive tape, and further comprising the step of removing said tape, after said step of forming the layer of shielding material.

19. A method according to claim 12, wherein the layer of shielding material is formed by one or more of spraying, dipping, immersion, electroplating, electroless plating, and electrolytic plating.

20. A method according to claim 12, wherein the molding compound is applied using block molding.

21. A method according to claim 20, wherein the step of forming the layer of shielding material comprises injection molding of the shielding material.

22. A method for manufacturing a package for a semiconductor device, comprising:
providing a leadframe including a lead and a connecting bar, the leadframe having a top surface and a bottom surface,
forming a first recess in the lead with respect to the top surface at an outer end of the lead adjacent to a boundary of the leadframe;
forming a second recess in the connecting bar with respect to the bottom surface at least at an end of the connecting bar adjacent to the boundary of the leadframe;
applying a molding compound over the leadframe using a pocket molding process, so that a portion of the leadframe adjacent to the boundary of the leadframe is not covered by the molding compound;
forming a layer of electrically conductive shielding material overlying the molding compound and contacting said portion of the leadframe not covered by the molding compound;
performing a singulation process at the boundary of the leadframe and aligned with the first recess and the second recess, thereby forming a package side face, the package side face including
shielding material disposed on an upper portion thereof,
an exposed portion of the molding compound,
an exposed first surface at the outer end of the lead, and
an exposed second surface at the end of the connecting bar.

23. A method according to claim 22, wherein said singulation process is one of a cutting process and a punching process.

24. A method according to claim 22, wherein the layer of shielding material is formed by one or more of spraying, dipping, immersion, electroplating, electroless plating, and electrolytic plating.

25. A method according to claim 22, wherein the step of forming the layer of shielding material comprises injection molding of the shielding material.
